(19) United States
(12) Patent Application Publication
(10) Pub. No.: US 2019/0326402 A1
(43) Pub. Date: Oct. 24, 2019

(54) GROUP III NITRIDE SEMICONDUCTOR SUBSTRATE AND METHOD FOR MANUFACTURING SAME

(71) Applicant: Panasonic Intellectual Property Management Co., Ltd., Osaka (JP)

(72) Inventor: TAKATOSHI OKAMOTO, Osaka (JP)

(21) Appl. No.: 16/292,414

(22) Filed: Mar. 5, 2019

(30) Foreign Application Priority Data
Apr. 18, 2018 (JP) 2018-079954

(51) Int. Cl. H01L 29/20; H01L 29/04; H01L 21/66; H01L 21/02

(52) U.S. Cl. CPC H01L 29/2003; H01L 29/045; H01L 21/02389; H01L 21/02433; H01L 22/12

(57) ABSTRACT

A Group III nitride semiconductor substrate capable of identifying a crystal orientation with high precision and a method for manufacturing the Group III nitride semiconductor substrate. The Group III nitride semiconductor substrate has a principal plane including a {0001} plane and is cleaved with reference to a prescribed crystal orientation. The Group III nitride semiconductor substrate includes a first orientation identification line which is located at an end portion of the principal plane when viewed in a plan view, a second orientation identification line which has an angular deviation relative to the prescribed crystal orientation smaller than that of the first orientation identification line, and a marker which identifies the second orientation identification line.

### TECHNICAL FIELD

The present disclosure relates to a Group III nitride semiconductor substrate and a method for manufacturing the same.

### BACKGROUND

In recent years, a self-standing gallium nitride substrate (hereinafter also referred to as a “GaN substrate”) has been manufactured, which is grown epitaxially by a hydride vapor phase epitaxy method (hereinafter also referred to as “HVPE”), as a Group III nitride semiconductor substrate for manufacturing a semiconductor laser (hereinafter also referred to as “LD”) which has ultraviolet to blue wavelengths used for reading and writing Blu-Ray and is used as a light source for welding.

As shown in FIG. 7, a GaN crystal configuring a substrate has a wurtzite hexagonal structure in which a gallium atom 21 and a nitrogen atom 23 are regularly arranged. The GaN crystal has a property of easily cracking (cleavage property) in a direction parallel to a (1-100) plane or in directions parallel to a crystal plane rotated by 60°, 120°, 180°, 240°, and 300° from the (1-100) plane (directions parallel to arrows 25 in FIG. 7).

In crystal geometry, a notation (a Miller notation) such as (hkil) is used to indicate a plane orientation of the crystal plane. The plane orientation of the crystal plane in a hexagonal crystal such as a group III nitride crystal is represented by (hkil). Here, h, k, i and l are integers called Miller indexes. A plane in the plane orientation (hkil) is referred to as a (hkil) plane. Further, a direction perpendicular to the (hkil) plane (a normal direction of the (hkil) plane) is referred to as an [hkil] direction. Further, {hkil} means a generic plane orientation including (hkil) and plane respective orientations crystal geometrically equivalent thereto, <hkil> means a generic direction including [hkil] and respective directions crystal geometrically equivalent thereto. Although minus signs in the Miller indexes are shown as overlines above numerical values in the drawings, the minus signs are represented by the minus sign instead of the overline above the numerals in convenience of notation in the description.

FIG. 8 and FIG. 9 show an example of a GaN substrate 26 for LD including the GaN crystal. FIG. 8 is a plan view of the GaN substrate 26, and FIG. 9 is a perspective view of the GaN substrate shown in FIG. 8. A thickness of the GaN substrate 26 is generally about 300 μm to 600 μm, and a common diameter is any of 50 mm, 75 mm, and 100 mm. An end portion (an outer periphery) of the GaN substrate 26 is chamfered (not shown) for the purpose of preventing cracking of the GaN substrate 26. Further, a principal plane of the GaN substrate 26 is mirror surface-like, and an opposite plane thereof (a back plane) is generally mirror surface-like or satin-finished. When both planes are mirror surface-like and there is no impurity such as oxygen and a metal element in the GaN crystal, the GaN substrate 26 is transparent to visible light.

Further, the principal plane of the GaN substrate 26 is formed by a (0001) plane of the GaN crystal. If necessary, a chordal orientation flat 27 or a notch (not shown) which identifies the orientation of [1-100] is formed on the GaN substrate, and when both planes are mirror finished, a chordal index flat 28 is formed at the end portion of the substrate for the purpose of identifying the principal plane and the back plane. Further, a marker 29 (for example, an ID) for discriminating a manufacture history, and a principal plane or a back plane of the substrate may be formed at any position on the principal plane or the back plane.

FIG. 10 shows a structure of an end surface light emitting LD using the GaN substrate. As shown in FIG. 10, an end surface light emitting LD 56 has an elongated shape with a length of several hundreds of micrometers (40 in FIG. 10) and a width of several tens of micrometers (39 in FIG. 10). Further, a device layer 41 in which an active layer 31 is sandwiched between an n-type cladding layer 32 and a p-type cladding layer 33 is disposed on a GaN substrate 30, and the p-type cladding layer 33 is processed to have one or a plurality of ridges. A p-side electrode 34 and an n-side electrode 35 are disposed on an upper surface of the ridge of the p-type cladding layer 33 and on a lower surface of the GaN substrate 30, respectively. Reflecting mirrors 36 and 37 are disposed on an end surface at a side from which laser light 38 is emitted and on an end surface at the opposite side, respectively, and serve as resonators.

The end surface at the side from which the laser light 38 is emitted may be destroyed by heat in the LD 56 capable of realizing high light output of several W (hereinafter also referred to as a “high output LD”). Therefore, in order to prevent thermal destruction of the LD 56, there may be a window structure in which the crystal of the device layer 41 in the vicinity of the end portion at the light emitting plane side (for example, at a region represented by 42 in FIG. 10) is disordered.

An operating principle of the LD 56 is that a current is injected into the active layer 31 via the p-side electrode 34 and the n-side electrode 35, and thereby an electron from the n-type cladding layer 32 and an electron from the p-type cladding layer 33 flow into the active layer 31. Further, the electrons recombine in the active layer 31 and emit light with a specific wavelength. The light is amplified in the LD 56 (an optical waveguide). When an amount of the amplified light exceeds a certain fixed value by injecting the current into the LD 56, the laser light 38 is outputted from the reflecting mirror 37 at the emitting side with a low reflectance.

FIGS. 11A to 11F show process drawings for manufacturing the LD 56 using the GaN substrate 26. First, the GaN substrate 26 is prepared, on which the orientation flat 27, the index flat 28, the marker 29 indicating an ID and the like are formed (FIG. 11A). Subsequently, the device layer 41 formed of the nitride semiconductor which includes the p-type cladding layer, the n-type cladding layer, the active layer and the like is epitaxially grown on the (0001) plane which is the principal plane of the GaN substrate 26 using a vapor phase growth method such as a metal organic vapor phase epitaxy (hereinafter also referred to as a “MOCVD”) method and a molecular beam epitaxial growth (MBE) method (FIG. 11B). Thereafter, annealing, etching, cleaning and the like are performed on the device layer 41 to prepare a desired chip layout 51 (FIG. 11C). A plurality of LD chips 52 are disposed on the chip layout 51, and ridges 53 are formed on the p-type cladding layer of each of the LD chips 52.

Thereafter, the back plane of the GaN substrate 26 is polished to a thickness of about 100 μm, the n-side electrode 35 is formed on the surface of the GaN substrate 26, and the p-side electrode (not shown) is formed on the ridge 53 of the p-type cladding layer of the device layer 41 (FIG. 11D). Then, the laminated body is divided into bar-shaped pieces 54 (hereinafter also referred to as a “bar”) in which the LD chips 52 are disposed in a lateral direction, and reflecting mirrors (not shown) are formed on both end surfaces 55 of each of the bars 54 (FIG. 11E). Thereafter, each of the bars 54 is cut in a direction perpendicular to a longitudinal direction thereof, so as to obtain a plurality of LDs 56 (FIG. 11F).

As shown in FIG. 11E, the laminated body is divided into a plurality of bars 54 by utilizing the cleavability of the GaN crystal (the GaN substrate 26). When the GaN substrate 26 has the (0001) plane as the principal plane, a width direction of the LD is formed in parallel with a cleavage direction 16 of the (1-100) plane. Accordingly, the cleavage occurs at boundaries 63 between the LD chips 52 by placing scribes 60 from the end side of the chip layout 51 to apply a mechanical load as shown in FIG. 12A, and thus the GaN substrate is divided into a plurality of bars 64 as shown in FIG. 12B.

The chip layout 51 shown in FIG. 11C is generally performed with reference to the orientation flat 27 that shows the crystal orientation <1-100> formed on the GaN substrate 26. More specifically, the orientation flat 27 is optically recognized, and a mask pattern and an angle of the GaN substrate 26 are aligned such that the recognized orientation flat 27 and the width direction of each of the LD chips 52 (LD 56) are parallel to each other. Then, an exposure is performed via the mask pattern by an exposure device, and a position of the chip layout 51 is determined. That is, in determining the position of the chip layout 51, the orientation flat 27 indicating the crystal orientation is utilized instead of measuring the crystal orientation of the GaN substrate 26 with X-ray diffraction (hereinafter also referred to as “XRD”) or the like.

In addition, the orientation flat 27 is also utilized for alignment in performing annealing, cleaning, and etching of the device layer 41, and electrode formation. That is, the orientation flat 27 is applied not only to position determination of the chip layout 51 but also to simple alignment and the like in electrode formation.

Therefore, high precision is required for the orientation flat that identifies the orientation of the GaN substrate. The following two methods are known as a method for forming an orientation flat on the GaN substrate. The two methods are: (a) a method for forming an orientation flat by utilizing a cleavage property of a crystal after slicing a cylindrical ingot to obtain a disc-shaped semiconductor substrate or after growing the device layer (JP-A-2006-290697 (Patent Document 1)); and (b) a method for forming a true orientation flat by correcting a deviation amount and cutting a temporary orientation flat along a desired crystal orientation after the temporary orientation flat is formed on a disk-shaped GaN substrate (JP-A-2015-202986 (Patent Document 2)).

In determining an arrangement of the chip layout 51, an absolute value of a deviation amount (hereinafter referred to as “orientation flat precision”) of the orientation flat 27 of the GaN substrate 26 with respect to the crystal orientation <1-100> of the GaN crystal 26 is required to be small.

More specifically, when the width direction of each of the LD chips 52 (LD 56) of the chip layout 51 determined from the orientation flat 27 and the cleavage direction 16 are deviated from each other as shown in FIG. 13A, the end surface of each of the LD chips 52 included in the bars 65 obtained by the cleavage is oblique as shown in FIG. 13B. That is, since the boundaries 63 between the chips in the chip layout and the cleavage plane are deviated from each other, a good LD cannot be obtained. Even if the angle of the GaN substrate and the like is corrected in advance in the chip layout 51 after measuring the orientation flat precision, an error is likely to occur during the correction. Therefore, even if such correction is made, the boundaries 63 between the chips of the chip layout and the cleavage direction 16 are likely to be deviated from each other, making it difficult to obtain a good LD.

Further, when the orientation flat precision is low, a dimension of the window of the LD may become smaller or larger. When the dimension of the window is small, a light emitting operation of the LD is likely to fail due to thermal destruction of the end surface. Meanwhile, when the dimension of the window is large, alight emitting characteristic of an optical axis of the laser light 38 is likely to change, an unacceptable variation occurs in the reliability and light emission characteristics required for the high output LD. From these viewpoints, it is also necessary to preciously manufacture the orientation flat of the GaN substrate.

In the method described in Patent Document 1 or Patent Document 2, when the orientation flat precision does not satisfy a desired value, the orientation flat cannot be reprocessed. Therefore, when a GaN substrate with low orientation flat precision is generated, the GaN substrate must be discarded or used for another application.

More specifically, when attempting to reprocess the orientation flat prepared by the method of Patent Document 1 or Patent Document 2, it is necessary to prepare a new orientation flat on a side inner than the initial orientation flat formed on the GaN substrate. Therefore, a length of the reprocessed orientation flat is longer than a desired length. For example, when the diameter of the GaN substrate is 50 mm and the length of the initial orientation flat is 16 mm, the length of the reprocessed orientation flat is 18 mm. Therefore, the length of the orientation flat is 2 mm longer by one reprocessing.

Since a gap is generated between a susceptor (not shown) and the GaN substrate 26 during a film forming of the device layer 41 and a flow of source gas is disturbed when the length of the orientation flat is excessively long, the desired device layer 41 cannot be obtained. Meanwhile, when the length of the orientation flat is excessively short, the chip layout 51 cannot be performed accurately.

For this reason, it is necessary that the length of the orientation flat of the GaN substrate is within a range of ±1.0 mm based on a generally determined length. In contrast, the length exceeds the range by one reprocessing in the related art. Therefore, the orientation flat can be formed only once in the formation of the GaN substrate requiring high orientation flat precision. That is, the formation of the orientation flat hinders stable provision of the GaN substrate for LD.

The present disclosure has been made in view of the above matters, and an object is to stably provide a Group III nitride semiconductor substrate capable of identifying a crystal orientation with high precision.

### SUMMARY

The present disclosure provides the following Group III nitride semiconductor.

A Group III nitride semiconductor substrate which has a principal plane including a {0001} plane and is cleaved with reference to a prescribed crystal orientation, includes: a first orientation identification line which is located at an end portion of the principal plane when viewed in a plan view; a second orientation identification line which has an angular deviation with respect to the prescribed crystal orientation smaller than that of the first orientation identification line; and a marker which identifies the second orientation identification line.

The present disclosure also provides the following method for manufacturing the Group III nitride semiconductor substrate.

A method for manufacturing the Group III nitride semiconductor substrate includes: preparing a substrate which is formed of a Group III nitride semiconductor and has a principal plane including a {0001} plane; forming a first orientation identification line with a laser at an end portion of the principal plane of the substrate when viewed in a plan view; measuring an angular deviation of the first orientation identification line with respect to a prescribed crystal orientation of the substrate; forming a second orientation identification line with the laser, the second orientation identification line having an angular deviation with respect to the prescribed crystal orientation of the substrate smaller than that of the first orientation identification line; and providing a marker that identifies the second orientation identification line.

According to the present disclosure, it is possible to stably manufacture a Group III nitride semiconductor substrate capable of identifying a crystal orientation with high precision.

### BRIEF DESCRIPTION OF THE DRAWINGS

FIG. 1 is an illustrative view showing a positional relationship among a shape, a crystal orientation, and a cleavage direction of a GaN substrate according to an illustrative embodiment of the present disclosure.

FIG. 2 is a perspective illustrative view of the GaN substrate shown in FIG. 1.

FIG. 3 is an illustrative view showing a positional relationship among a shape, a crystal orientation, and a cleavage direction of a GaN substrate according to another illustrative embodiment of the present disclosure.

FIG. 4 is a perspective illustrative view of the GaN substrate shown in FIG. 3.

FIG. 5 is an illustrative view showing a positional relationship among a shape, a crystal orientation, and a cleavage direction of a GaN substrate according to yet another illustrative embodiment of the present disclosure.

FIG. 6 is a perspective illustrative view of the GaN substrate shown in FIG. 5.

FIG. 7 is an illustrative view showing a structure and a direction of easily cleaving of a GaN crystal.

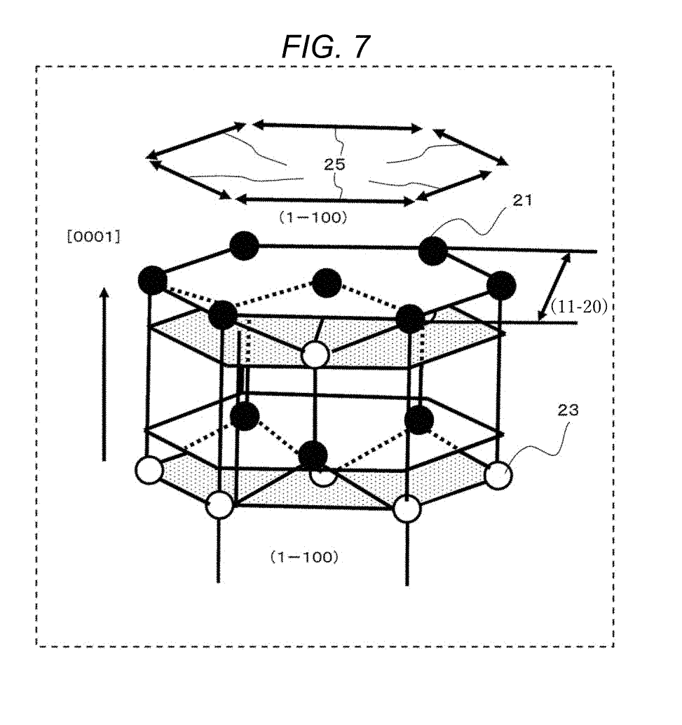

FIG. 8 is an illustrative view showing a positional relationship among a shape, a crystal orientation, and a cleavage direction of a related-art GaN substrate.

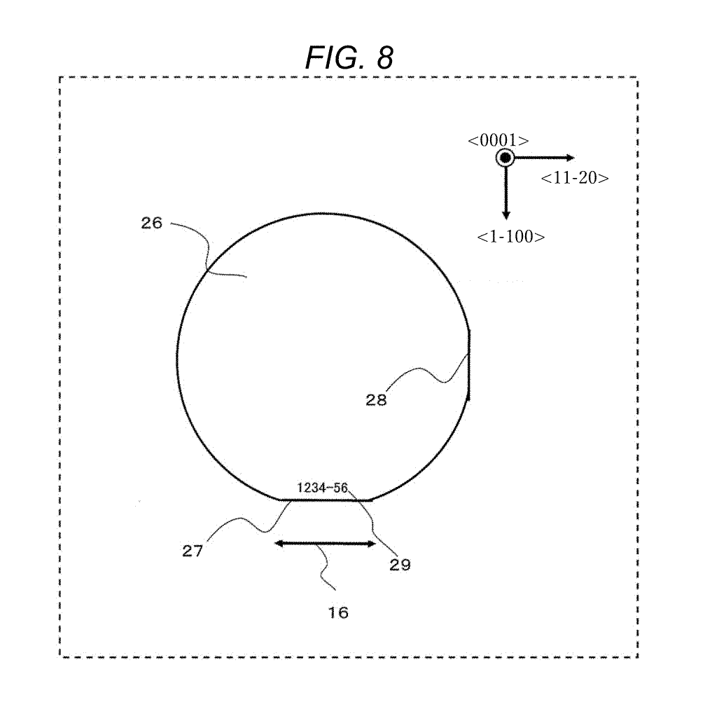

FIG. 9 is a perspective illustrative view of the GaN substrate shown in FIG. 8.

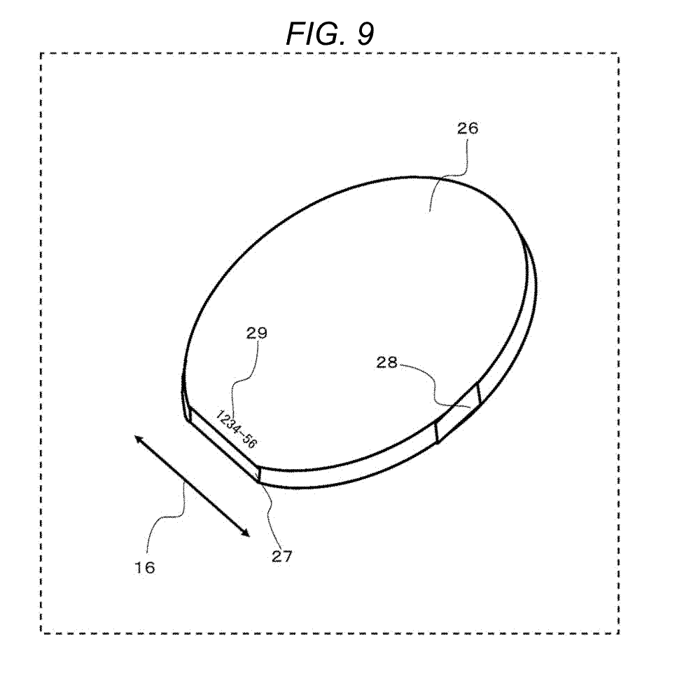

FIG. 10 is an illustrative view showing an illustrative configuration of an LD.

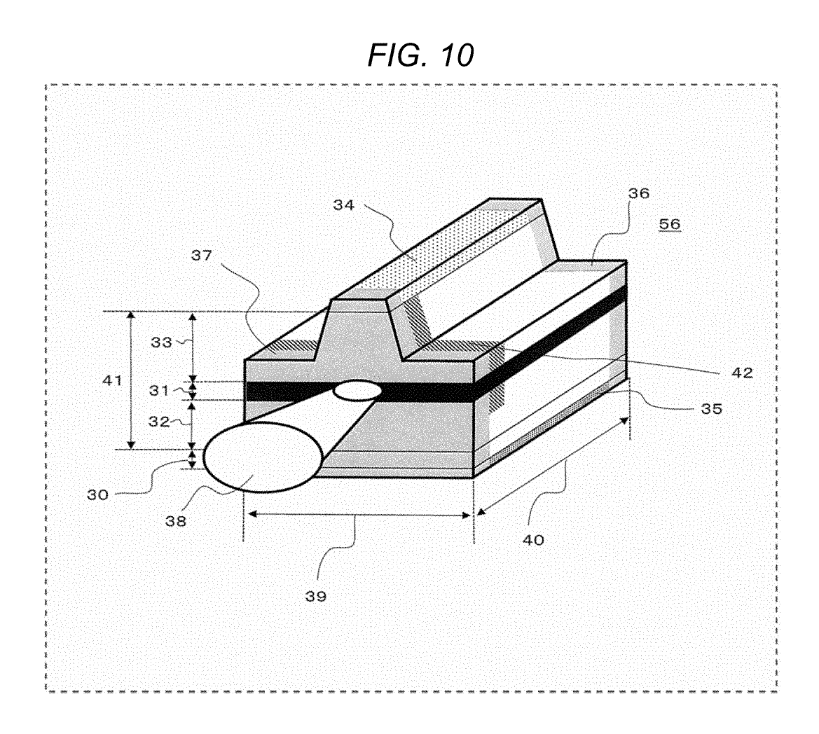

FIG. 11A to FIG. 11F are illustrative views showing preparation of an LD based on the related-art GaN substrate.

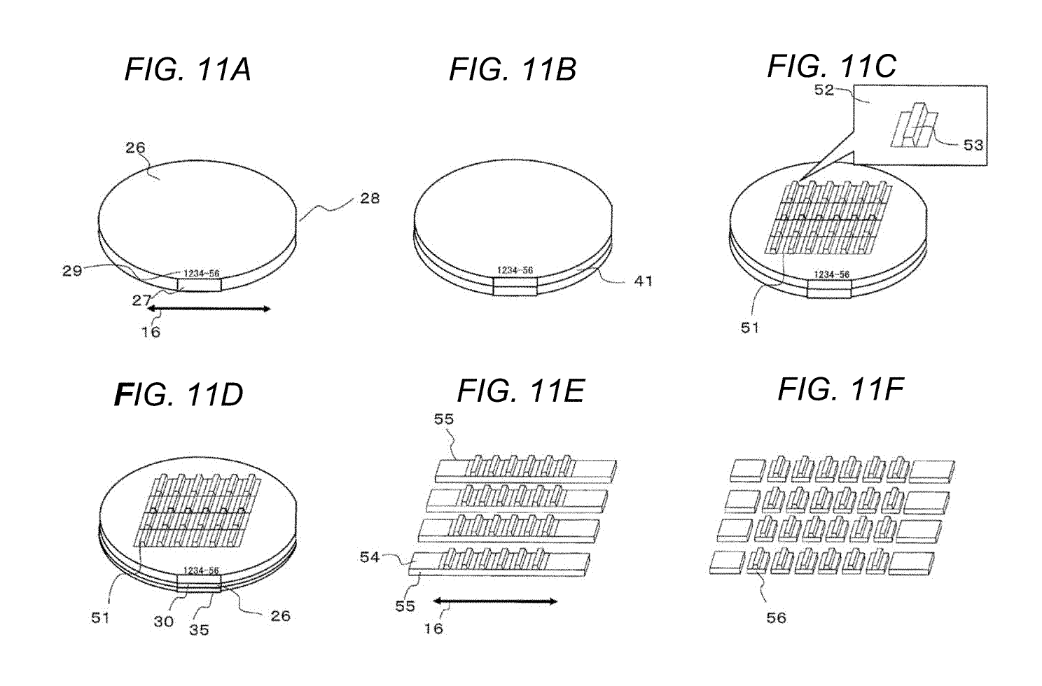

FIG. 12A and FIG. 12B are illustrative views showing a plurality of bars formed in a state where a cleavage direction and a chip layout are consistent with each other.

FIG. 13A and FIG. 13B are illustrative views showing a plurality of bars formed in a state where a cleavage direction and a chip layout are not consistent with each other.

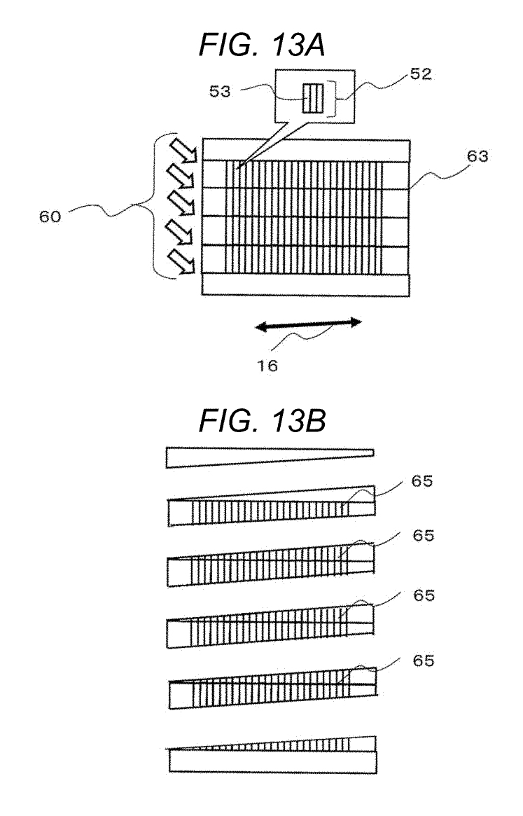

FIG. 14A to FIG. 14H are illustrative views showing a method for manufacturing a GaN substrate according to an illustrative embodiment of the present disclosure.

FIG. 15A to FIG. 15F are illustrative views showing formation of an orientation identification line according to an illustrative embodiment of the present disclosure.

FIG. 16A and FIG. 16B are illustrative views showing a method for measuring a deviation between an orientation identification line and a cleavage direction of the GaN substrate.

FIG. 17 is a photograph in which a line width and a fluctuation of an orientation identification line of the present disclosure are observed with a microscope.

### DETAILED DESCRIPTION OF PREFERRED EMBODIMENTS

Hereinafter, illustrative embodiments of the present disclosure will be explained with reference to the drawings.

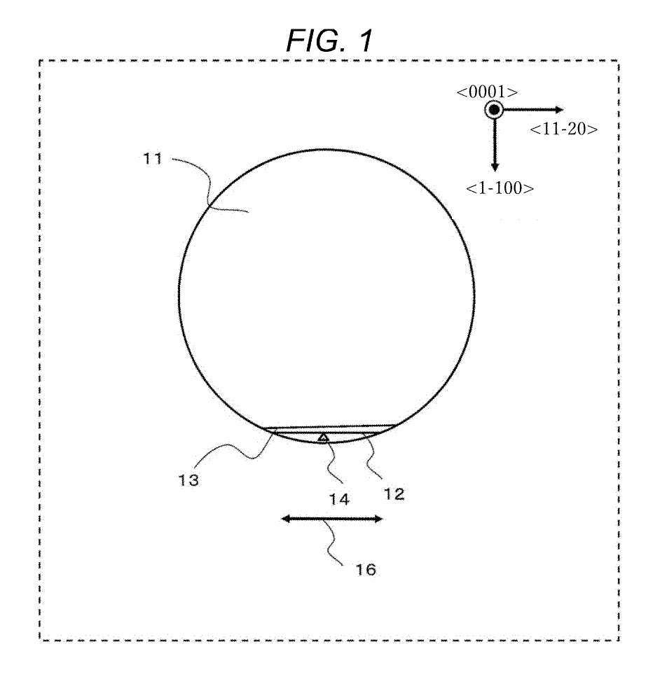

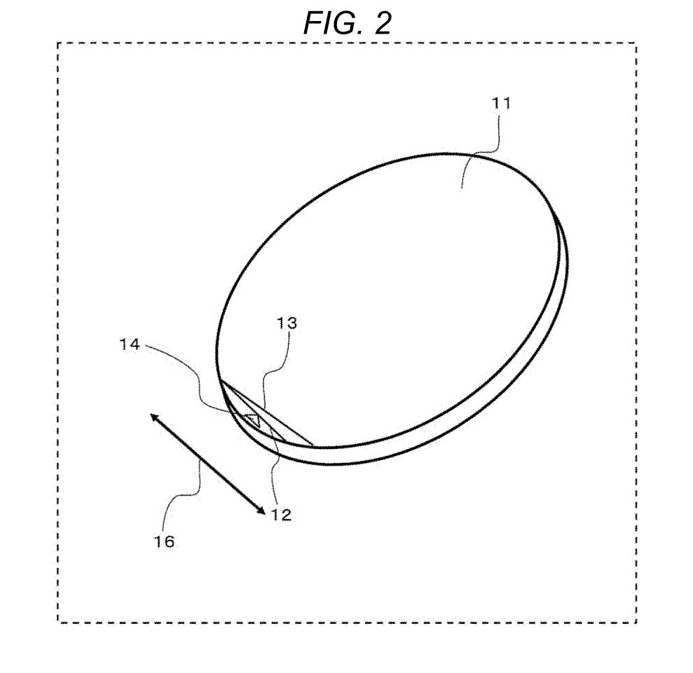

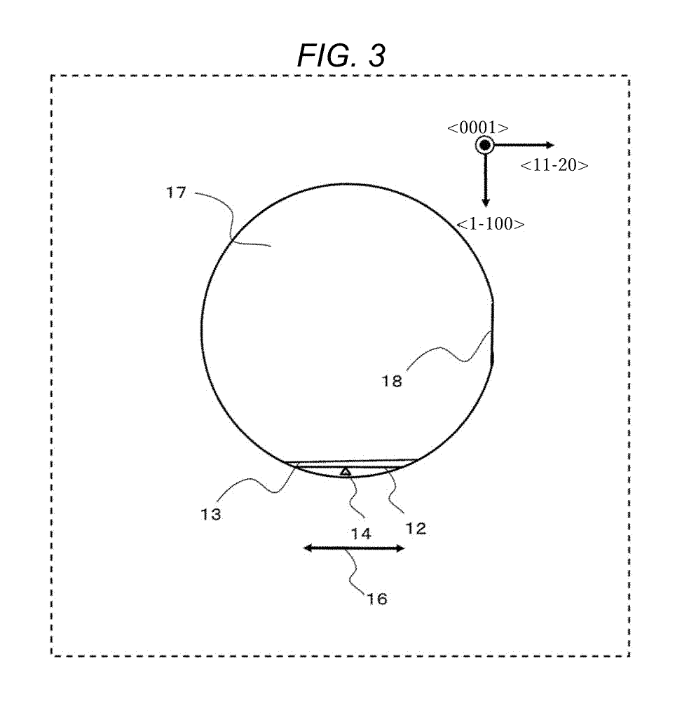

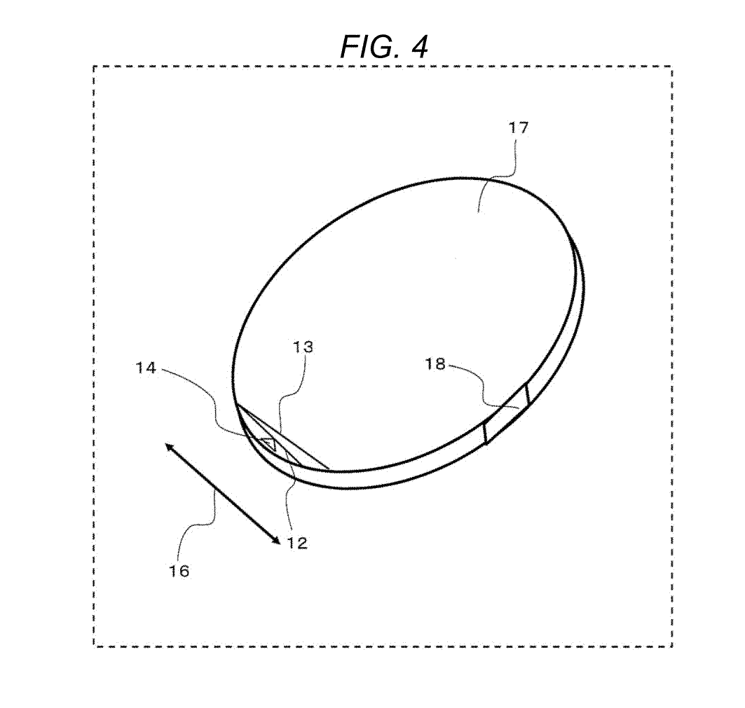

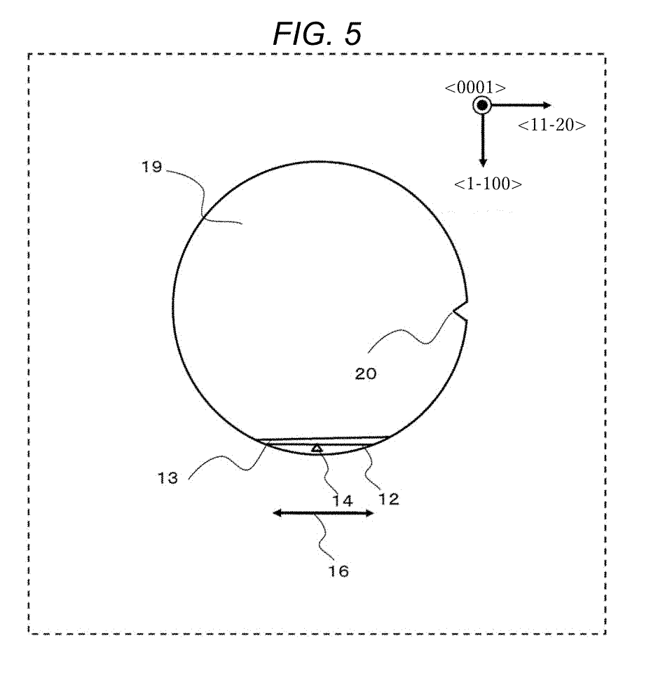

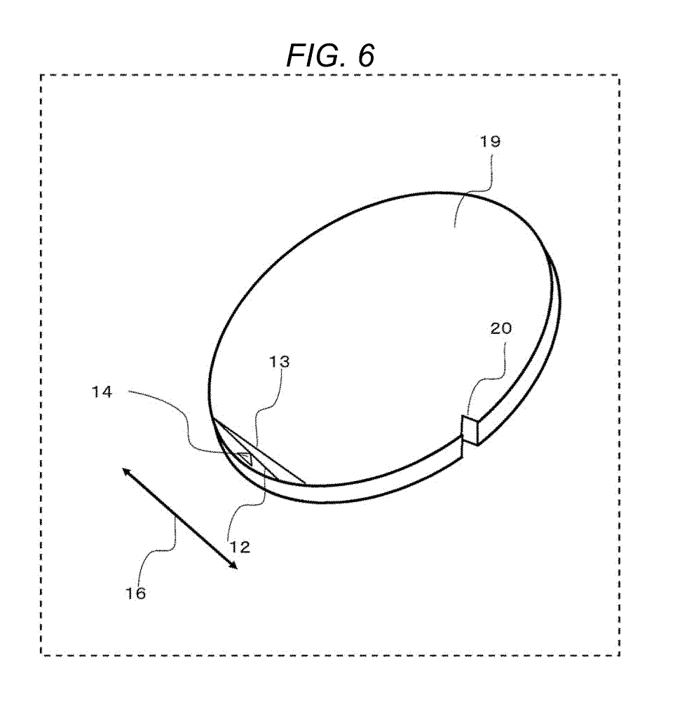

For example, as shown in FIG. 1 and FIG. 2, a Group III nitride semiconductor substrate 11 according to an illustrative embodiment of the present disclosure has a principal plane including a {0001} plane, and is used by cleaving with reference to a prescribed crystal orientation (parallel to a direction indicated by 16 in the figures). Further, a first orientation identification line 13 is provided on an end portion of the principal plane of the Group III nitride semiconductor substrate 11 when viewed in a plan view, and a second orientation identification line 12 having an angle deviation with respect to the prescribed crystal orientation smaller than that of the first orientation identification line is further provided. Further, the Group III nitride semiconductor 11 is also provided with a marker 14 that identifies the second orientation identification line. The first orientation identification line 13, the second orientation identification line 12, and the marker 14 may be recognizable when the principal plane of the Group III nitride semiconductor substrate 11 is viewed in a plan view, or may be provided on the principal plane of the Group III nitride semiconductor substrate 11, or may be provided on a back plane, or may be provided inside the Group III nitride semiconductor substrate 11 as will be described later. Here in this embodiment, the first orientation identification line 13, the second orientation identification line 12, and the marker 14 are formed by irradiation with a laser having a prescribed wavelength. FIG. 3 and FIG. 4 show a Group III nitride semiconductor substrate 17 according to another illustrative embodiment. The group III nitride semiconductor substrate 17 is the same as the Group III nitride semiconductor substrate 11 except for including an orientation flat 18. FIG. 5 and FIG. 6 further show a Group III nitride semiconductor substrate 19 according to yet another illustrative embodiment. The group III nitride semiconductor substrate 19 is the same as the Group III nitride semiconductor substrate 11 except for including a notch 20.

In the Group III nitride semiconductor substrate of this illustrative embodiment, an orientation identification line formed by laser irradiation is used instead of the related-art orientation flat in order to know the crystal orientation of the GaN substrate. The reason is that the line width and the fluctuation can be accurately controlled with the improvement of a laser irradiation device, and furthermore, the yield of the Group III nitride semiconductor substrate can be increased according to the method.

The line width is 50 μm to 300 μm when a related-art long-focus and long-pulse laser irradiation device using a CO₂ laser of 10 μm in wavelength irradiates a GaN crystal with a line. At this time, the fluctuation of the line is ±5% of the line width, that is, about ±2.5 μm to 15 μm.

For example, when a GaN substrate with a diameter of 50 mm is required to form an orientation identification line such that a deviation amount with respect to a prescribed crystal orientation falls within ±0.03°, it is necessary that the line prepared by the laser irradiation device has an inclination and a fluctuation with respect to the crystal orientation falling within ±8 μm in total. Nevertheless, a fluctuation of 5 μm to 30 μm occurs in an irradiation line obtained with a long-pulse laser irradiation device. That is, it can be considered that the fluctuation alone exceeds the required precision. Therefore, in the related art, an identification line prepared by the laser irradiation is not effective as an identification line of the crystal orientation.

In contrast, as a result of repeated studies by the inventor, it is discovered that an irradiation line with a line width of about 2 μm can be imparted to the GaN substrate, and the fluctuation thereof can be ±0.2 μm if a laser with a wavelength of 532 nm and good absorption with respect to the GaN substrate is used and a short-pulse and short-focus laser irradiation device is used.

When identification of the crystal orientation required for a GaN substrate for LD application is performed by the orientation identification line, it is necessary that the inclination and the fluctuation of the orientation identification line fall within ±8 μm in total as described above. In contrast, the fluctuation (±0.2 μm) of the orientation identification line formed by the short-pulse and short-focus laser irradiation device can be said to be a sufficiently small value.

Based on such knowledge, the inventor has reached a conclusion that a line formed by a specific laser irradiation device can be practically used for crystal orientation identification in the GaN substrate for LD.

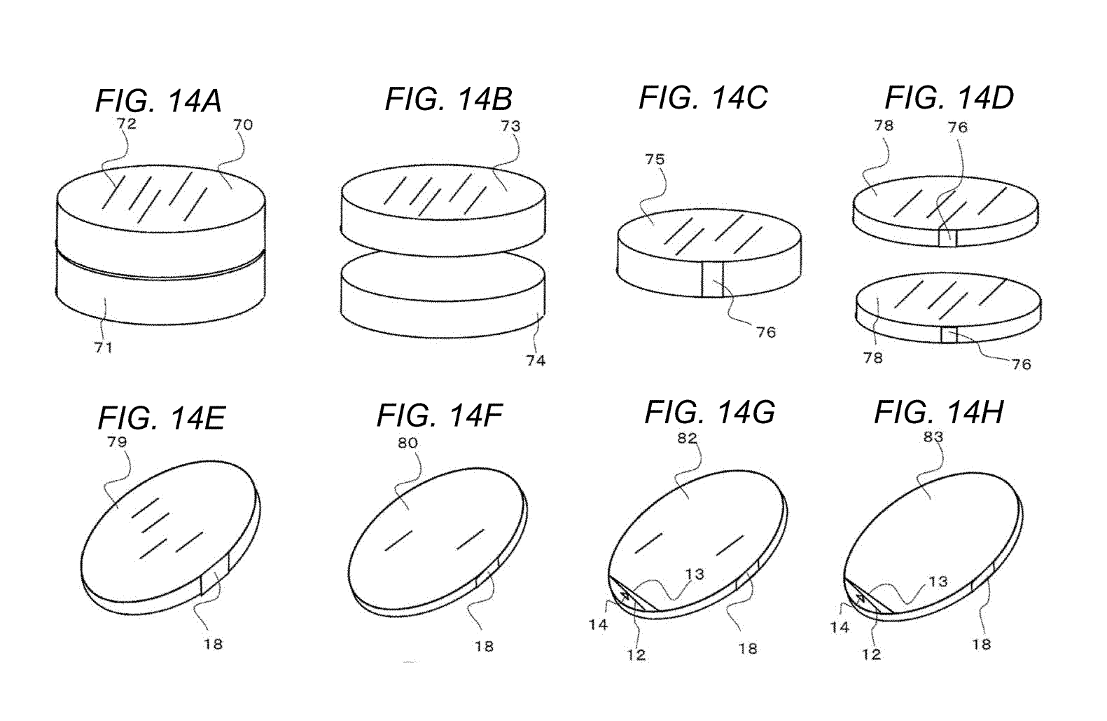

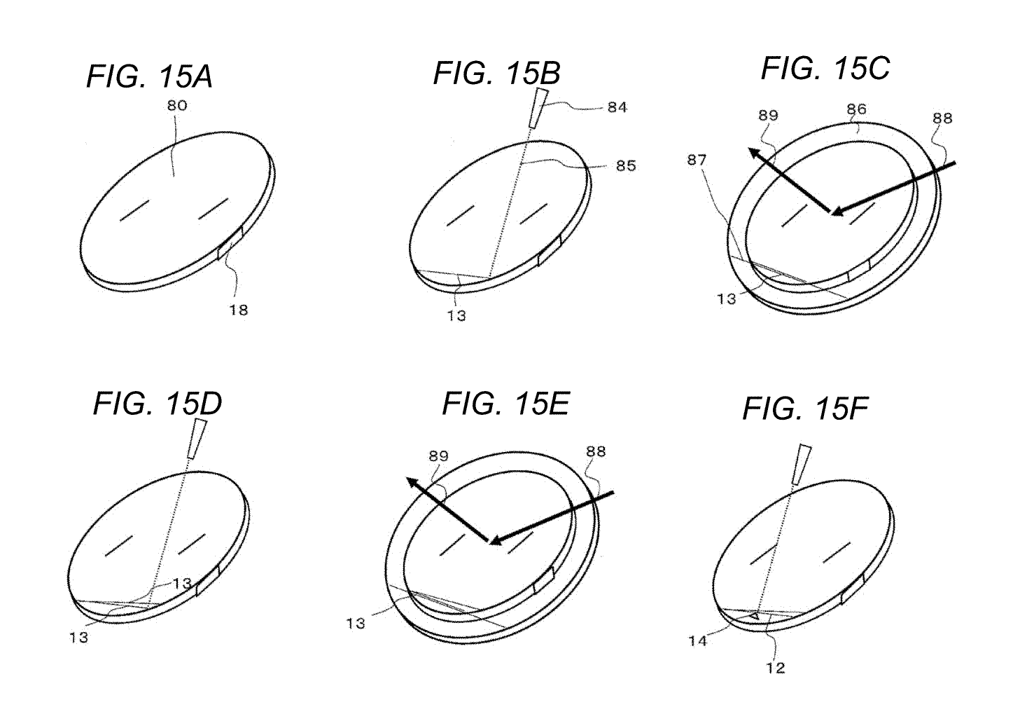

Hereinafter, a method for manufacturing a GaN substrate according to an illustrative embodiment of the present disclosure and an illustrative method for performing a chip layout of an LD using the obtained GaN substrate will be described in detail. FIG. 14 shows manufacturing of the GaN substrate, and FIG. 15 shows a method for forming the orientation identification line.

First, a columnar GaN crystal (an ingot) 70 is prepared as a base material of the GaN substrate in the method for manufacturing the GaN substrate as shown in FIG. 14 (FIG. 14A). In preparing the ingot 70, the GaN crystal is grown on, for example, a seed substrate 71 which has a {0001} plane (more specifically, a (0001) plane) as a principal plane in a crystal orientation <0001>, specifically, for example, in a direction of [0001]. A size of the ingot 70 is set to be a size obtained by adding a processing margin of an end surface of about 5 mm to 10 mm to a diameter of a desired GaN substrate. For example, when the diameter of the desired GaN substrate is 50 mm, the ingot 70 with a diameter of about 60 mm is prepared. Further, a thickness of the ingot 70 is set to be a thickness obtained by adding a loss of about 100 μm to 300 μm of the ingot 70 due to the cutting method to a product of the thickness and the number of the GaN substrate cut out from the ingot 70.

There is no particular restriction on a growth method of the ingot 70, a material of the seed substrate 71 for growing the ingot 70, and a shape of the seed substrate surface. Although examples of the growth method of the ingot 70 include an HVPE method, other methods of a liquid phase method such as a Na flux method, or an ammonothermal method may also be used. The material of the seed substrate 71 can be, for example, GaN, Al₂O₃, ScAlMgO₄, or the like. Further, an unevenness processing for the purpose of reducing a crystal defect may be performed on the seed substrate 71 by using a known technique. Further, the crystal orientation of the seed substrate 71 may be inclined by about 0.4° to 10° to the direction of <1-100> from the direction of <0001>, and an axis of the cylinder of the ingot 70 and the crystal orientation <0001> may be shifted to each other, so as to form the seed substrate 71 having an off angle. More specifically, the crystal orientation of the seed substrate 71 may be inclined by about 0.4° to 10° to the direction of [1-100] from the direction of [0001], and the axis of the cylinder of the ingot 70 and the crystal orientation [0001] may be shifted to each other, so as to form the seed substrate 71 having an off angle. In this embodiment, there is no restriction on an absolute number of the crystal defect generated in growing the ingot 70 or a distribution of the crystal defect of the GaN substrate.

Subsequently, the GaN ingot 70 grown on the seed substrate 71 is separated into a seed substrate 74 and a GaN ingot 73 by applying a known processing technique such as etching, laser processing, and grinding with various abrasive grains (FIG. 14B).

Thereafter, a cylindrical shape is obtained using a known processing technique such as hollowing, cylindrical grinding, and parallel grinding. Further, a principal plane and a back plane are processed to be parallel to each other to form an ingot 75 having a desired shape (FIG. 14C). In performing the cylindrical processing, a GaN crystal orientation (the crystal orientation [1-100] in this illustrative embodiment) is determined in advance using XRD. Then, a temporary identification 76 capable of identifying a specific crystal orientation is formed on a part of an outer circumferential surface of the GaN crystal. The shape of the temporary identification 76 may be an orientation flat or a notch. In FIG. 14, an orientation flat 76 is formed.

Subsequently, two or more substrates 78 are obtained from the ingot 75 (FIG. 14D). The cutting of the ingot 75 can use known cutting means such as a wire saw and an inner peripheral blade. At this time, an off angle also can be formed by shifting the slicing direction and the principal plane of the ingot 75 by a fixed amount.

Thereafter, a process of trimming the substrate 78 such that the diameter of the substrate 78 is within a prescribed range, chamfering of the end surface (the outer circumference), and formation of the orientation flat 18 are performed by using a chamfering device (chamfer) which utilizes a tape, a grindstone, and the like (FIG. 14E).

The orientation flat 18 is formed with reference to the temporary identification 76 prepared as described above. In this embodiment, the orientation flat 18 is processed to be within ±5.0° with respect to a crystal orientation [11-20]. In this illustrative embodiment, the orientation flat 18 is formed at a position shifted by 90° counterclockwise from the temporary identification 76. At this time, if the substrate 78 is disposed in the chamfering device and the alignment is performed, the orientation flat precision can be easily increased. A notch may be formed instead of the orientation flat.

When a substrate 79 with a diameter of 50 mm and a thickness of 350 μm is formed, the chamfer amount of the end surface is preferably 100 μm on the principal plane side and 50 μm on the back plane side, and the length of the orientation flat 18 is preferably 16 mm±1 mm. At this time, the angular deviation amounts between the orientation flat 18 and the crystal orientations [11-20] and [1-100] are measured using a known technique of an XRD device.

Subsequently, the principal plane and the back plane of the substrate 79 are finished to mirror surfaces by sequentially using a known device such as a grinding device using a diamond grindstone or a tape, a lapping device using a diamond abrasive grain, and a CMP (Chemical Mechanical Polish) device using a slurry of colloidal silica and the like and a polishing pad of a nonwoven fabric, and a thickness variation is adjusted. Accordingly, a substrate 80 transparent to visible light can be obtained.

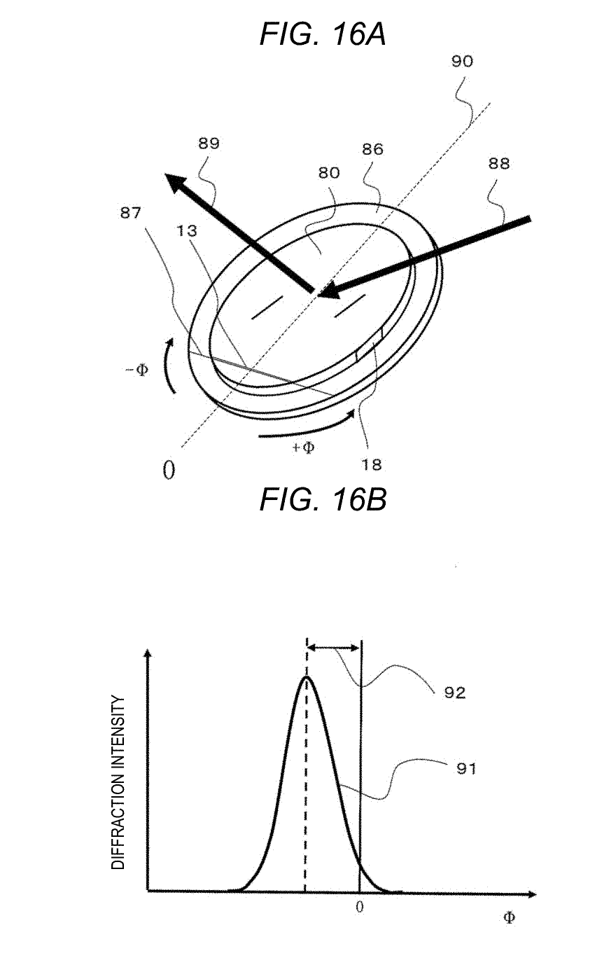

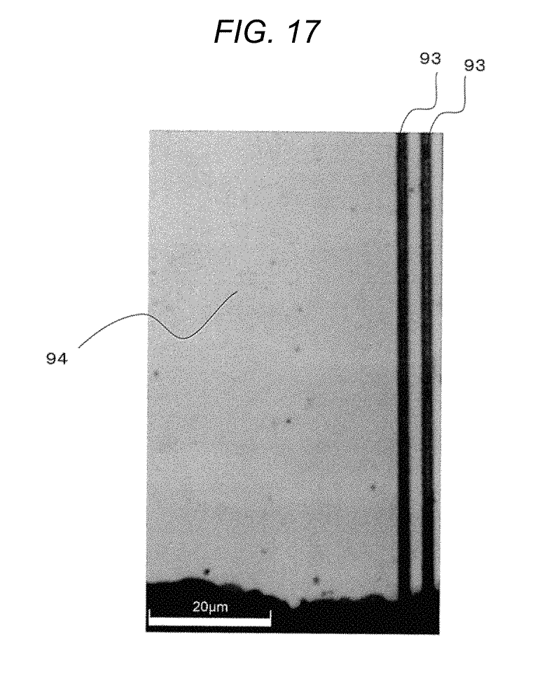

Thereafter, the first orientation identification line 13 and the second orientation identification line 12 are formed on a principal plane of the substrate 80 (FIG. 14F and FIG. 14G). The formation of these orientation identification lines will be described in more detail with reference to FIG. 15, FIG. 16 and FIG. 17.

A short-pulse and short-focus laser irradiation device 84 irradiates the transparent substrate 80 (FIG. 15A) having mirror surfaces on both planes with laser light 85, the laser irradiation device 84 using a laser having a wavelength of 532 nm with good absorption by the substrate 80. Accordingly, the first orientation identification line 13 having a prescribed line width and further having a fluctuation is formed on a principal plane of the substrate 82 (FIG. 15B).

The irradiation of the laser light 85 may be performed on the back plane of the substrate 80. The inside of the substrate 80 can also be irradiated with the laser light 85 according to the short-pulse and short-focus laser irradiation device 84.

In alignment of the angle of the first orientation identification line 13, first, the principal plane and the back plane are determined by a known method such as a difference in chamfer amount of the substrate 80. Then, a prescribed crystal orientation (the crystal orientation [1-100] in this embodiment) of the substrate 80 is determined by measuring the crystal orientation and the off angle of the substrate 80 with the XRD device. The irradiation device is aligned to be parallel to the obtained crystal orientation, and the first orientation identification line 13 is drawn by laser irradiation at a desired position.

When there is the orientation flat 18 (or the notch) at a position different from a position where the first orientation identification line 13 is formed, the position where the first orientation identification line 13 is formed may be adjusted with reference to an angular deviation of the orientation flat 18 from the orientation [1-100]. This makes it easier to simply form the first orientation identification line 13.

It is possible to provide a line having a deviation amount within ±5° with respect to the desired crystal orientation in any of the methods. In the case of this illustrative embodiment, the first orientation identification line 13 can be provided with a deviation amount within ±5° from a cleavage direction of the crystal orientation [1-100] (a direction perpendicular to the crystal orientation [1-100]).

When the diameter of the GaN substrate is 50 mm, it is desirable to form the first orientation identification line 13 with a length of 16 mm±1 mm. For example, the following irradiation conditions can be set as irradiation conditions that the line width of the irradiation line is 2 μm and the fluctuation of the line is within ±0.2 μm. FIG. 17 shows a photograph in which an orientation identification line 93 is actually formed on the surface of a GaN substrate 92 under the following conditions.

Laser Irradiation Conditions

Laser wavelength: 532 nm

Pulse: 15 picoseconds

Laser output: 1.00 W

Frequency: 250 kHz

Scan speed: 125 mm/sec

After the first orientation identification line 13 is formed, the deviation amount of the first orientation identification line 13 with respect to the crystal orientation [1-100] is measured by the XRD device (FIG. 15C). Specifically, as shown in FIG. 16A, a reference line 87 is formed perpendicularly to a reference angle 0° of the device on an adsorption stage 86 of the XRD device on which the GaN substrate 80 is disposed. The line width is preferably narrower than the first orientation identification line 13, and more preferably 1.5 μm or less.

Next, it is visually confirmed whether the first orientation identification line 13 of the GaN substrate 80 fixed to the adsorption stage 86 completely covers the reference line 87. At this time, if the reference line 87 is completely covered, it can be determined that there is no angular deviation between the first orientation identification line 13 and the reference line of the device, or the first orientation identification line 13 can be formed with a deviation within an allowable range with respect to a required precision. Thereafter, the stage 86 is rotated clockwise and counterclockwise to obtain a diffraction spectrum 91 of the crystal orientation [1-100] shown in FIG. 16B. A deviation amount 92 between an angle at which the maximum intensity of the diffraction spectrum 91 is obtained and a reference angle 90 of the device corresponds to the deviation amount of the first orientation identification line 13 with respect to the crystal orientation [1-100] of the GaN substrate. For measurement of the deviation amount, it is necessary that the GaN substrate 80 is made transparent by mirror finishing.

If the result of measuring the deviation amount of the orientation identification line 13 with respect to the crystal orientation [1-100] is within target precision, preferably within ±0.03°, the method proceeds to the formation of the marker 14 described later. Meanwhile, it is easy to expect that the first orientation identification line 13 formed at the first time is approximate processing and does not fall within the desired precision. When the first identification line 13 does not fall within the desired precision, the formation of the orientation identification line at the second time and the measurement of the deviation amount thereof are subsequently performed.

The alignment providing an identification line is performed based on the deviation amount between the first orientation identification line 13 formed previously and the crystal. More specifically, the irradiation position of the laser light 85 is adjusted based on the deviation amount to form the first orientation identification line 13 for the second time and thereafter (FIG. 15D). Further, this step is repeated until a deviation amount of a newly formed first orientation identification line 13 with respect to the crystal orientation [1-100] is within the prescribed range. When the first orientation identification line 13 has already been formed twice or more, the irradiation position of the laser light 85 is determined with reference to the line having the smallest deviation with respect to the crystal orientation [1-100] among the previously formed first orientation identification lines 13.

For example, when the formation of the first orientation identification line 13 is the fourth time, the irradiation position of the laser light 85 is adjusted by using the line having the smallest deviation amount of the crystal orientation among the first orientation identification lines 13 formed until the third time. Further, when the formation of the first orientation identification line 13 is the fifth time, the irradiation position of the laser light is adjusted by using the first orientation identification line 13 having the smallest deviation amount among the first orientation identification lines 13 formed until the fourth time.

When the alignment is performed based on the orientation identification line formed previously, the deviation amount easily falls within the desired range due to the adjustment using the orientation flat 18 or the adjustment based on the measurement by the XRD device. The reason for this is that the correction amount of the irradiation device when the first orientation identification line 13 is formed for the second time is smaller than the correction amount of the irradiation device when the first orientation identification line 13 is formed for the first time, and accordingly the deviation amount of the first orientation identification line 13 with respect to the crystal orientation [1-100] decreases.

Every time a new first orientation identification line 13 is formed, the deviation amount is measured by the above method (FIG. 15E). According to the illustrative method, it is possible to make the deviation amount with respect to the crystal orientation [1-100] within ±0.03° by forming the orientation identification line for 5 times or less, generally.

In the illustrative method, if the deviation amount with respect to the crystal orientation [1-100] can be within ±0.03°, it can be equal to the deviation amount of a good crystal orientation prepared by related-art orientation flat formation. The obtained GaN substrate is discarded (specifically, about 5% to 30% is discarded) when the deviation amount is less than the above range in a related-art method, while it is not necessary to discard the GaN substrate even if the deviation amount does not fall within the above range according to the above illustrative method.

When the orientation identification line 13 is given more than 5 times, an inconvenience such as overlapping of the first orientation identification lines 13 occurs, making it difficult to recognize the crystal orientation. Therefore, the plane on which the first orientation identification line 13 is formed is polished to have a thickness equal to or greater than the depth of the first orientation identification line 13, and the first orientation identification line 13 may be erased from the principal plane of the GaN substrate and re-formed.

Next, the first orientation identification line 13 in which the deviation amount with respect to the crystal orientation [1-100] is smallest and the deviation amount falls within ±0.03° is taken as the second orientation identification line 12. The second orientation identification line 12 is generally the first orientation identification line 13 formed last.

Thereafter, the marker 14 which identifies the second orientation identification line 12 is provided (FIG. 15F). The marker 14 may be provided to any of the principal plane, the back plane, and the inside of the GaN substrate 82.

FIG. 15F shows a case where the first orientation identification line 13 is formed twice to obtain the second orientation identification line 12 as an example, and a triangular mark is formed near the center of the second orientation identification line 12 and below the second orientation identification line 12 and on the principal plane of the GaN substrate using the laser irradiation device. The marker 14 is not limited to the triangular mark but may be a circle, a rectangle, a letter or other marking.

When it is necessary to make the back plane satin-finished to identify the front or back plane of the obtained GaN substrate 82, the GaN substrate 82 on which the second orientation identification line 12 is formed is immersed in KOH and the back plane thereof is processed to be satin-finished using a single-side lapping device (FIG. 14G).

Since it is difficult to recognize the second orientation identification line 12 due to the formation of the satin-finished plane when the first orientation identification line 13, the second orientation identification line 12, and the marker 14 are formed on the back plane, it is necessary to increase the depth or adjust the roughness to be small by adjusting the output of the laser irradiation.

Next, finish polishing is performed on the surface of the GaN substrate 82 as necessary (FIG. 14H). A polishing method can be a known method, and the finish polishing is performed on the principal plane of the GaN substrate 82. It is desirable to use a polishing pad formed of a polyurethane material to reduce processing deterioration of the surface. It is possible to obtain a flat surface with the surface roughness Ra of the principal plane of the GaN crystal 83 being less than 1.0 nm by the finish polishing.

After the finish polishing is performed, the GaN substrate 83 is cleaned by being immersed in weak alkali and acid using a known technique, so as to remove impurities of inorganic and organic components attached to the principal plane. If a finish-polished and cleaned GaN substrate 83 is subjected to inspections of appearance, shape and the like, the GaN substrate of this embodiment is completed if passing the inspections.

Next, a method for performing the chip layout 51 of the LD using the GaN substrate will be described.

When the GaN substrate is used, the second orientation identification line 12 is specified based on the marker 14 after the formation of the device layer 41. Then, the chip layout is formed on the GaN substrate using an exposure device after the angle of the mask pattern is aligned by utilizing the microscope and the like so as to be parallel to the specified second orientation identification line 12.

At this time, if the deviation amount of the second orientation identification line 12 with respect to the crystal orientation [1-100] is within ±0.03° and is formed within the above line width and the fluctuation range, it is possible to arrange the chip layout fitting to the cleavage direction of the GaN substrate.

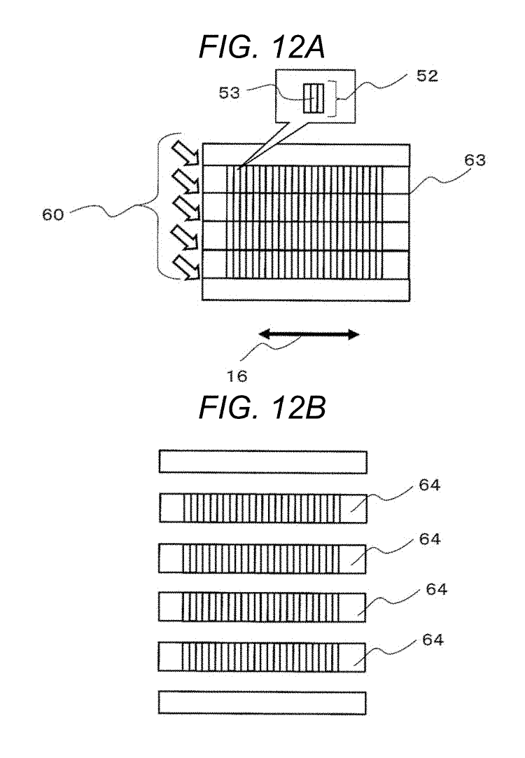

Therefore, after the chip layout is formed, the shape of the bar 64 formed by the cleavage processing as shown in FIG. 12A is stabilized. When alignment is necessary in the device layer forming, chip layout forming, and electrode forming device, the orientation flat and the notch of the GaN substrate may be utilized, and it is not necessary to greatly change the manufacturing steps of the related-art LD according to the above illustrative method.

Although the present disclosure has been described in detail with reference to the illustrative embodiments, it is not limited to the above illustrative embodiments. For example, although a case of forming the GaN substrate has been described as an example, any material may be used as long as it is a Group III nitride (the crystal system is the same). For example, the Group III nitride semiconductor substrate may be obtained by using a crystal such as AlGaInN and AlN. Further, as the orientation used as a reference in forming the second orientation identification line 12, in addition to [1-100], equivalent orientations <1-100>, more specifically, [10-10], [01-10], [−1100], [−1010], and [0-110] which have a cleavage property rotated every 60° from [1-100] also can obtain the same effect.

The difference between the related art and the present disclosure is whether the high precision identification of crystal orientation is performed by a second orientation identification line formed by laser irradiation or by an orientation flat. When the second orientation identification line is formed, reprocessing can be performed until the high precision orientation identification line is obtained.

In the formation of the orientation flat in the related art, when the deviation amount with respect to the crystal orientation does not satisfy a desired value, the GaN substrate is discarded as the defective product, or diverted to the GaN substrate for LED application and the like regardless of the orientation flat precision. However, according to the illustrative method of the present disclosure, such a defective product does not occur and the yield of the Group III nitride semiconductor substrate is increased.

According to the illustrative embodiments and method according to the present disclosure, it is possible to stably supply a Group III nitride semiconductor substrate capable of accurately identifying a crystal orientation, and the Group III nitride semiconductor substrate is very useful as the substrate for LD and the like.

Although the present disclosure has been described with reference to the aforementioned embodiments and methods, this description is not meant to be construed in a limiting sense. Various modifications of the disclosed embodiments and methods as well as alternative embodiments and methods will become apparent to persons skilled in the art. It is therefore contemplated that the appended claims will cover any such modifications.

What is claimed is:

1. A Group III nitride semiconductor substrate which has a principal plane including a {0001} plane and is cleaved with reference to a prescribed crystal orientation, the Group III nitride semiconductor substrate comprising:
a first orientation identification line which is located at an end portion of the principal plane when viewed in a plan view;
a second orientation identification line which has an angular deviation with respect to the prescribed crystal orientation smaller than that of the first orientation identification line; and
a marker which identifies the second orientation identification line.

2. The Group III nitride semiconductor substrate according to claim 1, further comprising:
an orientation flat or a notch at a position different from the second orientation identification line.

3. A method for manufacturing a Group III nitride semiconductor substrate, the method comprising:
preparing a substrate which is formed of a Group III nitride semiconductor and has a principal plane including a {0001} plane;
forming a first orientation identification line with a laser at an end portion of the principal plane of the substrate when viewed in a plan view;
measuring an angular deviation of the first orientation identification line with respect to a prescribed crystal orientation of the substrate;
forming a second orientation identification line with a laser, the second orientation identification line having an angular deviation with respect to the prescribed crystal orientation of the substrate smaller than that of the first orientation identification line; and
providing a marker that identifies the second orientation identification line.

4. The method for manufacturing a Group III nitride semiconductor substrate according to claim 3, further comprising:
forming an orientation flat or a notch on the Group III nitride semiconductor substrate, wherein the second orientation identification line is formed at a position different from the orientation flat and the notch.

5. The method for manufacturing a Group III nitride semiconductor substrate according to claim 4,
wherein a wavelength of the laser forming the first orientation identification line, the second orientation identification line, and the marker is 532 nm.
